(19) United States
(12) Patent Application Publication
(10) Pub. No.: US 2024/0412995 A1
(43) Pub. Date: Dec. 12, 2024

(54) GUIDED DIFFUSION DEVICE BRACKETS AND METHODS FOR DIFFUSION DEVICE RETENTION

(71) Applicant: ENTEGRIS, INC., Billerica, MA (US)

(72) Inventors: Mark V. Smith, Colorado Springs, CO (US); Shawn D. Eggum, Lonsdale, MN (US); Matthew A. Fuller, Colorado Springs, CO (US)

(21) Appl. No.: 18/732,527

(22) Filed: Jun. 3, 2024

Related U.S. Application Data
(60) Provisional application No. 63/471,379, filed on Jun. 6, 2023.

(51) Int. Cl. H01L 21/673

(52) U.S. Cl. CPC H01L 21/67393

(57) ABSTRACT

Brackets are provided on an interior of a substrate container to receive and retain a diffusion device. The brackets include an receiver having a first internal cross-sectional area and a retention region having a second internal cross-sectional area, with the first internal cross-sectional area being larger than the second internal cross-sectional area. The bracket can include a second receiver on an opposite end of the bracket from the first receiver, such that the bracket can be inverted for use on either side of the substrate container. The brackets can receive diffusion devices when the diffusion devices are inserted from an exterior of the substrate container.

### FIELD

This disclosure is directed to substrate containers, particularly brackets for receiving and retaining diffusion devices within such substrate containers.

### BACKGROUND

Substrate containers can include diffusion devices to introduce gases, such as purge gases, within the container. The diffusion devices are typically installed in the substrate containers by operations performed within the body of the container, such as snap-fitting the diffusion devices to features provided on the interior of the substrate container.

### SUMMARY

This disclosure is directed to substrate containers, particularly brackets for receiving and retaining diffusion devices within such substrate containers.

By having an opening larger than the retaining region of the diffusion device bracket, a diffusion device can be received and guided into position even when the diffusion device is being inserted from outside of the substrate container. This can reduce or eliminate the number of operations that are performed within the container body itself, and thus reduce particle generation or introduction of contaminants that can result from such operations. This in turn improves the cleanliness of the substrate containers and the resulting yields from processing of substrates using such containers in the process.

In an embodiment, a substrate container includes a shell and a bracket disposed on the shell. The bracket at least partially defines a space. The bracket includes an receiver having a first internal cross-sectional area at an end configured to receive a diffusion device and a retention region having second internal cross-sectional area at along a length of the bracket. The first internal cross-sectional area is larger than the second internal cross-sectional area, and the second internal cross-sectional area is at least a cross-sectional area of the diffusion device the end is configured to receive.

In an embodiment, the substrate container further includes a second bracket disposed on the shell. The second bracket at least partially defines a second space. The second bracket includes an receiver having a third internal cross-sectional area at an end configured to receive a second diffusion device and a fourth internal cross-sectional area at a retention region along a length of the bracket. The third internal cross-sectional area is larger than the fourth internal cross-sectional area, and the fourth internal cross-sectional area is at least a cross-sectional area of the diffusion device the end is configured to receive.

In an embodiment, the substrate container includes the diffusion device, wherein the diffusion device is at least partially surrounded by the bracket and the diffusion device extends through a portion of the bracket having the second internal cross-sectional area.

In an embodiment, the diffusion device has a chamfer at an end configured to be inserted into the bracket.

In an embodiment, the diffusion device is radiused at an end configured to be inserted into the bracket.

In an embodiment, the bracket includes a second end opposite the end configured to receive the diffusion device, wherein at the second end, the bracket includes a second receiver having a third internal cross-sectional area, the third internal cross-sectional area larger than the second internal cross-sectional area. In an embodiment, the third internal cross-sectional area and the first internal cross-sectional area are equal.

In an embodiment, the bracket includes a plurality of openings along a length of the bracket.

In an embodiment, the bracket is disposed on a back wall of the shell. In an embodiment, the bracket is attached to the back wall by a weld.

In an embodiment, a method of inserting a diffusion device into a substrate container includes directing the diffusion device into an opening defined by an receiver provided at an end of a bracket. The bracket has a first internal cross-sectional area at the receiver and a second internal cross-sectional area in a retention region along a length of the bracket. The first internal cross-sectional area is larger than the second internal cross-sectional area.

In an embodiment, the method further includes directing the diffusion device through an opening in a shell of the substrate container prior to directing the diffusion device into the receiver.

In an embodiment, the diffusion device is joined to a purge module when the diffusion device is directed through the opening in the shell of the substrate container.

In an embodiment, when the diffusion device is inserted into the substrate container, the diffusion device extends through a portion of the bracket having the second internal cross-sectional area.

In an embodiment, the method further includes directing a second diffusion device into an opening defined by an receiver provided at an end of a second bracket. The second bracket has a third internal cross-sectional area at the receiver and a fourth internal cross-sectional area in a retention region along a length of the bracket. The third internal cross-sectional area is larger than the fourth internal cross-sectional area. In an embodiment, the method further includes directing the second diffusion device through an opening in a shell of the substrate container prior to directing the second diffusion device into the opening defined by the receiver of the second bracket. In an embodiment, the second diffusion device is joined to a purge module when the second diffusion device is directed through the opening in the shell of the substrate container.

### DRAWINGS

FIG. 1 shows a front view of a substrate container according to an embodiment.

FIG. 2 shows a bracket according to an embodiment.

FIG. 3 shows a bracket according to an embodiment.

FIG. 4 shows a flowchart of a method for providing a diffusion device within a substrate container according to an embodiment.

### DETAILED DESCRIPTION

This disclosure is directed to substrate containers, particularly brackets for receiving and retaining diffusion devices within such substrate containers.

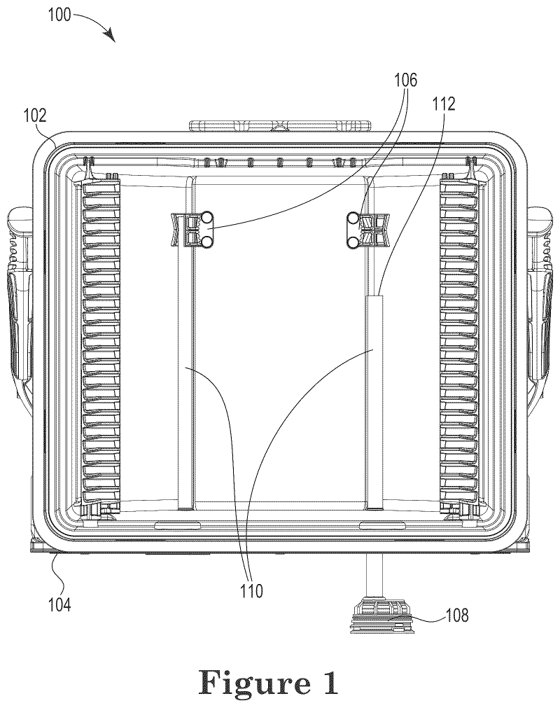

FIG. 1 shows a front view of substrate container according to an embodiment. Substrate container 100 includes shell 102 and bottom plate 104. The substrate container 100 further includes brackets 106, purge modules 108, and diffusion devices 110.

Substrate container 100 is a configured to contain substrates, such as semiconductor wafers or any other suitable substrates, during transportation, storage, and/or processing of those substrates. Substrate container 100 includes shell 102, which can define an internal space capable of accommodating one or more substrates. The shell 102 can define the internal space by way of top, bottom, side, and back walls with an open front side provided to allow the insertion or removal of the substrates from the internal space.

Bottom plate 104 can be included in substrate container 100. Bottom plate 104 can be configured to facilitate handling of the substrate container, include interfaces for receiving and retaining purge modules 108 and/or diffusion devices 110, or the like. In an embodiment, bottom plate 104 is a conveyor plate of the substrate container 100.

Brackets 106 are brackets configured to receive and retain the diffusion devices 110 when the diffusion devices are fully inserted into the substrate container 100, for example as shown for the bracket 106 and diffusion device 110 provided on the left side of the substrate container 100 shown in FIG. 1. The brackets can be attached to the shell 102, for example being attached to the back wall of shell 102.

Purge modules 108 can optionally be included in substrate container 100. Purge modules 108 can be configured to interface with a source of purge gas, such as a purge gas line of a tool that substrate container 100 is configured to be used with. In an embodiment, purge module 108 can include multiple components that are each inserted into a purge port included in bottom plate 104 and/or shell 102 and attached via a mechanical connection such as a retainer. In an embodiment, purge module 108 can be an assembly of components attached to one another that can be received and retained in a purge port included in bottom plate 104 and/or shell 102. In an embodiment, purge module 108 includes a diffusion device 110. In an embodiment, a diffusion device 110 can be attached to the purge module 108. In an embodiment, the diffusion device 110 can be configured to be retained in part within shell 102 by features provided on one or more of the purge module 108, bottom plate 104, and shell 102.

Diffusion devices 110 are configured to allow diffusion of gas, such as a purge gas, into the internal space defined by shell 102. In an embodiment, the gas provided by diffusion devices 110 can be used to purge the internal space defined by shell 102, for example to remove contaminants including but not limited to moisture, volatile organic compounds (VOCs) and the like. The gas can be, as non-limiting examples, nitrogen, an inert gas, clean dry air (CDA), extra clean dry air (xCDA), or the like. Diffusion devices 110 can be, for example, diffuser towers. Diffusion devices 110 can be made of a porous material to allow the diffusion of the gas through the diffusion devices 110. The diffusion devices 110 can receive the gas to be provided to the internal space by way of purge module 108. Diffusion devices 110 each have an end 112. The end 112 is shown in FIG. 1 as being flat, but in alternative embodiments, end 112 can be hemispherical, or a transition from the body of diffusion device 110 to end 112 can be beveled, chamfered, radiused, sharp-edged or otherwise shaped to facilitate insertion of the diffusion device 110 into the bracket 106.

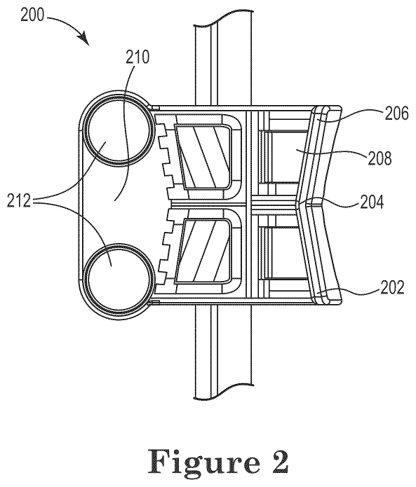

FIG. 2 shows a bracket according to an embodiment. Bracket 200 includes first receiver 202, retention region 204, and second receiver 206. Openings 208 can be defined in bracket 200. Bracket further includes attachment tab 210 and attachment points 212.

Bracket 200 is a bracket configured to receive and retain a portion of a diffusion device such as diffusion device 110 described above and shown in FIG. 1. Bracket 200 can be used as the brackets 106 provided in substrate container 100 described above and shown in FIG. 1.

A first receiver 202 is provided at a first end of bracket 200. The first receiver 202 can at least partially define a first internal cross-sectional area. The first internal cross-sectional area can be configured to receive the diffusion device without any interference with the diffusion device at the first receiver 202. In an embodiment, the shape of the first internal cross-sectional area can correspond to a shape of the cross-sectional area of the diffusion device. The first internal cross-sectional area is larger than the cross-sectional area of the diffusion device that is to be received and retained by bracket 200. The first internal cross-sectional area can be selected based on facilitation of the insertion of the diffusion device and avoiding interference with the capability of the substrate container to accommodate substrates. In an embodiment, the first internal cross-sectional area can be between 10% and 1000% larger than the cross-sectional area of the diffusion device to be used with bracket 200.

Retention region 204 can be provided along a length of the bracket 200 between the first end where first receiver 202 is provided and the second end where second receiver 206 is provided. The retention region 204 is a region of the bracket 200 that defines a second internal cross-sectional area configured to accommodate the diffusion device. The second internal cross-sectional area is configured to accommodate the diffusion device such that the diffusion device is retained in a particular position and/or alignment by the bracket 200. The second internal cross-sectional area is smaller in total area that either of the first internal cross-sectional area defined at first receiver 202 or a third internal cross-sectional area defined at second receiver 206. The second internal cross-sectional area is equal to or larger than the cross-sectional area of the diffusion device at a point along the diffusion device configured to extend through the retention region 204 when the diffusion device is fully inserted into the substrate container.

Second receiver 206 can be provided at a second end of bracket 200, opposite the first end where first receiver 202 is provided. The second receiver 206 can at least partially define a third internal cross-sectional area. The third internal cross-sectional area can be configured to receive the diffusion device. In an embodiment, the shape of the third internal cross-sectional area can correspond to a shape of the cross-sectional area of the diffusion device. The third internal cross-sectional area is larger than the cross-sectional area of the diffusion device that is to be received and retained by bracket 200. The third internal cross-sectional area can be selected based on facilitation of the insertion of the diffusion device and avoiding interference with the capability of the substrate container to accommodate substrates. In an embodiment, the third internal cross-sectional area can be between 10% and 1000% larger than the cross-sectional area of the diffusion device to be used with bracket 200. In an embodiment, the cross-sectional shape of bracket 200 is the same at each of first receiver 202 and second receiver 206. In an embodiment, the first internal cross-sectional area and the third internal cross-sectional area are each the same in total area. In an embodiment, the first internal cross-sectional area and the third internal cross-sectional area have different shapes and/or total areas.

By providing first and second receivers 202, 206 on either side of the retention region 204, the bracket 200 can be provided in a side-agnostic configuration where the bracket 200 can be installed to retain either a left-side diffusion device or a right-side diffusion device as those are shown in FIG. 1. The bracket 200 can be rotated 180 degrees between a position presenting the first receiver 202 to receive the diffusion device when the diffusion device is provided through the bottom of the shell of the substrate container and another position presenting the second receiver 206 to receive the diffusion device when the diffusion device is provided through the bottom of the shell of the substrate container, such that only one part must be manufactured but can be installed on either side of the back wall of the shell.

Openings 208 can be provided in the portion of bracket 200 including first and second receivers 202, 206 and retention region 204. The openings 208 can be sized and shaped to, for example, reduce the use of materials, reduce the obstruction of flow out of the diffusion structures, or the like.

Attachment tab 210 can extend from the portion of bracket 200 including the first and second receivers 202, 206 and retention region 204. Attachment tab 210 provides a region allowing attachment of the bracket 200 to the substrate container, for example attachment to the back wall of shell 102 as described above and shown in FIG. 1. In an embodiment, the attachment tab 210 can include attachment points 212 where the attachment to the substrate container is formed. In an embodiment, the entire attachment tab can be attached to the substrate container. The attachment of attachment tab 210 or attachment points 212 to the substrate container can be through any suitable attachment, including but not limited to welding such as ultrasonic welds, mechanical interfaces such as corresponding engagement features, the use of mechanical fasteners such as screws, adhesives, or the like.

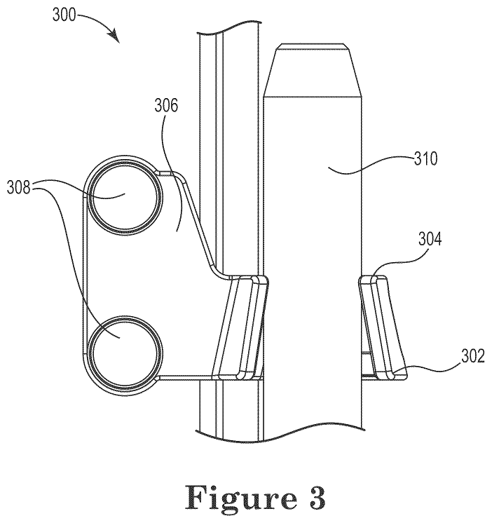

FIG. 3 shows a bracket according to an embodiment. Bracket 300 includes receiver 302, retention region 304, attachment tab 306, and attachment points 308. In FIG. 3, diffusion device 310 is shown.

Bracket 300 is a bracket configured to receive and retain a portion of a diffusion device such as diffusion device 110 described above and shown in FIG. 1. Bracket 300 can be used as the brackets 106 provided in substrate container 100 described above and shown in FIG. 1.

A receiver 302 is provided at a first end of bracket 200. The receiver 302 can at least partially define a first internal cross-sectional area. The first internal cross-sectional area can be configured to receive the diffusion device. In an embodiment, the shape of the first internal cross-sectional area can correspond to a shape of the cross-sectional area of the diffusion device. The first internal cross-sectional area is larger than the cross-sectional area of the diffusion device that is to be received and retained by bracket 300. The first internal cross-sectional area can be selected based on facilitation of the insertion of the diffusion device and avoiding interference with the capability of the substrate container to accommodate substrates. In an embodiment, the first internal cross-sectional area can be between 10% and 1000% larger than the cross-sectional area of the diffusion device to be used with bracket 300.

Retention region 304 can be provided along a length of the bracket 300. The retention region 304 is a region of the bracket 300 that defines a second internal cross-sectional area configured to accommodate the diffusion device. The second internal cross-sectional area is configured to accommodate the diffusion device such that the diffusion device is retained in a particular position and/or alignment by the bracket 300. The second internal cross-sectional area is smaller in total area that the first internal cross-sectional area defined at receiver 302. The third internal cross-sectional area is equal to or larger than the cross-sectional area of the diffusion device at a point along the diffusion device configured to extend through the retention region 304 when the diffusion device is fully inserted into the substrate container.

Attachment tab 306 can extend from the portion of bracket 300 including the first receiver 302 and retention region 304. Attachment tab 306 provides a region allowing attachment of the bracket 300 to the substrate container, for example attachment to the back wall of shell 102 as described above and shown in FIG. 1. In an embodiment, the attachment tab 306 can include attachment points 308 where the attachment to the substrate container is formed. In an embodiment, the entire attachment tab can be attached to the substrate container. The attachment of attachment tab 306 or attachment points 308 to the substrate container can be through any suitable attachment, including but not limited to welding such as ultrasonic welds, mechanical interfaces such as corresponding engagement features, the use of mechanical fasteners such as screws, adhesives, or the like.

In FIG. 3, diffusion device 310 is shown. As shown in FIG. 3, diffusion device 310 can include a chamfer at an end configured to facilitate insertion of the diffusion device 310 into bracket 300.

Bracket 300 can be particular to a side of the substrate container, for example, being configured to receive and retain only the left-side or only the right-side diffusion device within a substrate container. A bracket that is a mirror image of bracket 300 can be provided and installed in a substrate container such as substrate container 100 described above and shown in FIG. 1 in order to receive and retain the other of the left-side or right-side diffusion device.

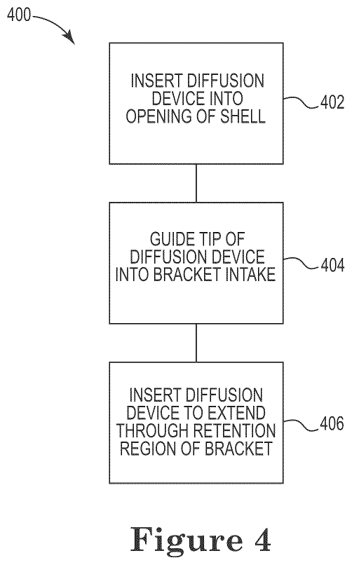

FIG. 4 shows a flowchart of a method for providing a diffusion device within a substrate container according to an embodiment. Method 400 includes inserting a diffusion device into an opening formed in a shell of a substrate container 402, directing a tip of the diffusion device into an receiver of a bracket inside the substrate container at 404, and inserting the diffusion device such that it extends through a retention region of the bracket at 406. The method 400 can optionally further be repeated for each diffusion device to be installed into the substrate container.

The diffusion device is inserted into an opening formed in the shell of the substrate container at 402. The diffusion device can be inserted into the opening from an exterior of the substrate container. In an embodiment, the diffusion device can be inserted by itself at 402. In an embodiment, the diffusion device can be attached to a purge module when inserted at 402. The opening formed in the shell can have a corresponding opening in the bottom plate, and in an embodiment, the diffusion device can also be inserted through the opening in the bottom plate at 402.

A tip of the diffusion device is directed into an receiver of the bracket at 404. The tip of the diffusion device can be a flat tip as shown in FIG. 1, or can be hemispherical or have a bevel, a chamfer, or radiusing. This tip can be directed such that when it passes into the bracket provided in the internal space of the substrate container, the tip is within the internal cross-sectional area defined by an receiver of the bracket, such as first receiver 202, second receiver 204, or receiver 302 as those are described above and shown in FIGS. 2 and 3.

The diffusion device is inserted such that it extends into or through a retention region of the bracket at 406. As the diffusion device continues to be inserted through the bracket, the diffusion device is guided by the narrowing internal cross-sectional area defined by the body of the bracket until the tip of the diffusion device passes through the retention region. In the retention region, the diffusion device is closely surrounded or contacted by the bracket, such that the diffusion device is retained in a particular position and/or orientation by the bracket. In an embodiment, the tip of the diffusion device is within the retention region of the bracket following the insertion at 406. In an embodiment, the tip of the diffusion device passes through the retention region of the bracket, and a portion of the body of the diffusion device is located within the retention region of the bracket following the insertion at 406.

### Aspects

It is understood that any of aspects 1-11 can be combined with any of aspects 12-18.

Aspect 1. A substrate container, comprising:
a shell; and
a bracket disposed on the shell,
wherein the bracket at least partially defines a space, the bracket including an receiver having a first internal cross-sectional area at an end configured to receive a diffusion device and a retention region having second internal cross-sectional area at along a length of the bracket, wherein the first internal cross-sectional area is larger than the second internal cross-sectional area, and the second internal cross-sectional area is at least a cross-sectional area of the diffusion device the end is configured to receive.

Aspect 2. The substrate container according to aspect 1, comprising a second bracket disposed on the shell, wherein the second bracket at least partially defines a second space, the second bracket including an receiver having a third internal cross-sectional area at an end configured to receive a second diffusion device and a fourth internal cross-sectional area at a retention region along a length of the bracket, wherein the third internal cross-sectional area is larger than the fourth internal cross-sectional area, and the fourth internal cross-sectional area is at least a cross-sectional area of the diffusion device the end is configured to receive.

Aspect 3. The substrate container of claim 2, wherein the second bracket is identical in shape to the first bracket.

Aspect 4. The substrate container according to any of aspects 1-3, further comprising the diffusion device, wherein the diffusion device is at least partially surrounded by the bracket and the diffusion device extends through a portion of the bracket having the second internal cross-sectional area.

Aspect 5. The substrate container according to any of aspects 1-4, wherein the diffusion device has a chamfer at an end configured to be inserted into the bracket.

Aspect 6. The substrate container according to any of aspects 1-5, wherein the diffusion device is radiused at an end configured to be inserted into the bracket.

Aspect 7. The substrate container according to any of aspects 1-6, wherein the bracket includes a second end opposite the end configured to receive the diffusion device, wherein at the second end, the bracket has a third internal cross-sectional area, the third internal cross-sectional area larger than the second internal cross-sectional area.

Aspect 8. The substrate container according to aspect 7, wherein the third internal cross-sectional area and the first internal cross-sectional area are equal.

Aspect 9. The substrate container according to any of aspects 1-8, wherein the bracket includes a plurality of openings along a length of the bracket.

Aspect 10. The substrate container according to any of aspects 1-9, wherein the bracket is disposed on a back wall of the shell.

Aspect 11. The substrate container according to aspect 10, wherein the bracket is attached to the back wall by a weld.

Aspect 12. A method of inserting a diffusion device into a substrate container, comprising directing the diffusion device into an opening defined by an receiver provided at an end of a bracket, the bracket having a first internal cross-sectional area at the receiver and a second internal cross-sectional area in a retention region along a length of the bracket, wherein the first internal cross-sectional area is larger than the second internal cross-sectional area.

Aspect 13. The method according to aspect 12, further comprising directing the diffusion device through an opening in a shell of the substrate container prior to directing the diffusion device into the opening defined by the receiver.

Aspect 14. The method according to aspect 13, wherein the diffusion device is joined to a purge module when the diffusion device is directed through the opening in the shell of the substrate container.

Aspect 15. The method according to any of aspects 12-14, wherein when the diffusion device is inserted into the substrate container, the diffusion device extends through the retention region.

Aspect 16. The method according to any of aspects 12-15, further comprising directing a second diffusion device into an opening defined by an receiver provided at an end of a second bracket, the second bracket having a third internal cross-sectional area at the receiver and a fourth internal cross-sectional area in a retention region along a length of the bracket, wherein the third internal cross-sectional area is larger than the fourth internal cross-sectional area.

Aspect 17. The method according to aspect 16, further comprising directing the second diffusion device through an opening in a shell of the substrate container prior to directing the second diffusion device into the opening defined by the receiver of the second bracket.

Aspect 18. The method according to aspect 17, wherein the second diffusion device is joined to a purge module when the second diffusion device is directed through the opening in the shell of the substrate container.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

1. A substrate container, comprising:
a shell; and
a bracket disposed on the shell,
wherein the bracket at least partially defines a space, the bracket including an receiver having a first internal cross-sectional area at an end configured to receive a diffusion device and a retention region having second internal cross-sectional area at along a length of the bracket, wherein the first internal cross-sectional area is larger than the second internal cross-sectional area, and the second internal cross-sectional area is at least a cross-sectional area of the diffusion device the end is configured to receive.

2. The substrate container of claim 1, comprising a second bracket disposed on the shell, wherein the second bracket at least partially defines a second space, the second bracket including an receiver having a third internal cross-sectional area at an end configured to receive a second diffusion device and a fourth internal cross-sectional area at a retention region along a length of the bracket, wherein the third internal cross-sectional area is larger than the fourth internal cross-sectional area, and the fourth internal cross-sectional area is at least a cross-sectional area of the diffusion device the end is configured to receive.

3. The substrate container of claim 2, wherein the second bracket is identical in shape to the first bracket.

4. The substrate container of claim 1, further comprising the diffusion device, wherein the diffusion device is at least partially surrounded by the bracket and the diffusion device extends through a portion of the bracket having the second internal cross-sectional area.

5. The substrate container of claim 1, wherein the diffusion device has a chamfer at an end configured to be inserted into the bracket.

6. The substrate container of claim 1, wherein the diffusion device is radiused at an end configured to be inserted into the bracket.

7. The substrate container of claim 1, wherein the diffusion device has a beveled edge at an end configured to be inserted into the bracket.

8. The substrate container of claim 1, wherein the diffusion device has a sharp edge at an end configured to be inserted into the bracket.

9. The substrate container of claim 1, wherein the bracket includes a second end opposite the end configured to receive the diffusion device, wherein at the second end, the bracket includes a second receiver having a third internal cross-sectional area, the third internal cross-sectional area larger than the second internal cross-sectional area.

10. The substrate container of claim 9, wherein the third internal cross-sectional area and the first internal cross-sectional area are equal.

11. The substrate container of claim 1, wherein the bracket includes a plurality of openings along a length of the bracket.

12. The substrate container of claim 1, wherein the bracket is disposed on a back wall of the shell.

13. The substrate container of claim 12, wherein the bracket is attached to the back wall by a weld.

14. A method of inserting a diffusion device into a substrate container, comprising directing the diffusion device into an opening defined by an receiver provided at an end of a bracket, the bracket having a first internal cross-sectional area at the receiver and a second internal cross-sectional area in a retention region along a length of the bracket, wherein the first internal cross-sectional area is larger than the second internal cross-sectional area.

15. The method of claim 14, further comprising directing the diffusion device through an opening in a shell of the substrate container prior to directing the diffusion device into the opening defined by the receiver.

16. The method of claim 15, wherein the diffusion device is joined to a purge module when the diffusion device is directed through the opening in the shell of the substrate container.

17. The method of claim 14, wherein when the diffusion device is inserted into the substrate container, the diffusion device extends through the retention region.

18. The method of claim 14, further comprising directing a second diffusion device into an opening defined by an receiver provided at an end of a second bracket, the second bracket having a third internal cross-sectional area at the receiver and a fourth internal cross-sectional area in a retention region along a length of the bracket, wherein the third internal cross-sectional area is larger than the fourth internal cross-sectional area.

19. The method of claim 18, further comprising directing the second diffusion device through an opening in a shell of the substrate container prior to directing the second diffusion device into the opening defined by the receiver of the second bracket.

20. The method of claim 19, wherein the second diffusion device is joined to a purge module when the second diffusion device is directed through the opening in the shell of the substrate container.
